(19) United States
(12) Patent Application Publication
(10) Pub. No.: US 2026/0169531 A1
(43) Pub. Date: Jun. 18, 2026

(54) POWER SUPPLY AND AIR GUIDE COVER APPLIED TO POWER SUPPLY

(71) Applicant: SEA SONIC ELECTRONICS CO., LTD., Taipei (TW)

(72) Inventors: Hung-Wei YANG, Taipei (TW); Chi-Hao CHANG, Taipei (TW)

(21) Appl. No.: 18/980,717

(22) Filed: Dec. 13, 2024

(51) Int. Cl. G06F 1/20; G06F 1/18; H05K 7/20

(52) U.S. Cl. CPC G06F 1/20; G06F 1/189; H05K 7/20145; G06F 2200/201

(57) ABSTRACT

A power supply includes a housing and an air guide cover. The housing includes two first side walls in parallel, and two second side walls in parallel and connected to the two first side walls. One of the two first side walls includes an input port and at least one air vent. One of the two first side walls provided with the input port is covered by the air guide cover, the air guide cover and one of the two first side walls provided with the input port jointly define a space communicating with the at least one first air vent. The air guide cover includes an opening that can be directly observable from one of the two second side walls, the opening is located on one side of the air guide cover and communicated with the space.

### FIELD OF THE INVENTION

The invention relates to a power supply, particularly a power supply that can ensure smooth heat dissipation airflow after adjusting installation direction.

### BACKGROUND OF THE INVENTION

The specifications of conventional power supplies are designed to correspond to the specifications of traditional computer cases, facilitating the assembly process. However, with the evolution of time, consumer demands for computer case configurations have become more diversified, leading to the development of various types of computer cases to optimize the internal arrangement. Despite this, the specifications of conventional power supplies are still based on those of traditional computer cases, which limits an orientation in which the power supply can be installed in modern cases. As a result, an internal space of current computer cases cannot be fully utilized during an assembly of the conventional power supply. Furthermore, if attempting to directly adjust an installation orientation of a conventional power supply in the computer case, the air guide path of the conventional power supply may be obstructed by the computer case, resulting in poor ventilation.

In this regard, TWM624626U discloses a power supply device installed in a computer case to provide power to the electronic devices assembled within the casing. The power supply device includes a housing with four sides: front, rear, left, and right. An AC input interface is installed on the rear side, and at least one DC output interface is installed on one of the left or right sides adjacent to the rear. Since the at least one DC output interface is positioned on either the left or right side of the housing, when the power supply device is installed in the computer case, it allows users to more easily connect power cords used by the electronic devices within the computer case to the at least one DC output interface.

In TWM624626U, the side where the at least one DC output interface is adjacent to the side where the AC input interface is located, thereby changing a position of the power cords within the computer case. This is, compared with the conventional power supplies, the concept of the side plug-in power supply is proposed in TWM624626U, addressing the issue where the DC output interface of conventional power supplies connected to the wires obstructs the air guide path inside the computer casing.

On the other hand, the design of the power supply device disclosed in TWM624626U alters the original structure of conventional power supplies, potentially rendering the previously used power supplies obsolete and leading to waste. Furthermore, both the power supply device disclosed in TWM624626U and the conventional power supplies are of a single form, and users cannot freely switch the configurations of the power supplies based on different types of computer cases.

### SUMMARY OF THE INVENTION

A main object of the invention is to improve the problem of the irregularity of the heat dissipation air flow caused by adjusting installation direction of the conventional power supply.

In order to achieve the above object, the invention provides a power supply, including a housing and an air guide cover. The housing includes two first side walls in parallel, and two second side walls in parallel and respectively connected to the two first side walls. One of the two first side walls is provided with an input port and at least one first air vent. One of the two first side walls provided with the input port is covered by the air guide cover. The air guide cover and one of the two first side walls provided with the input port jointly define a space, which is communicated with the at least one first air vent. The air guide cover includes an opening that can be directly observable from one of the second side walls, the opening is located on one side of the air guide cover and communicated to the space.

In one example, at least one of the two first side walls or at least one of the two second side walls is provided with at least one input port.

In one example, at least one of the two second side walls is provided with at least one second air vent.

In one example, a length of each of the two first side walls is larger than that of each of the two second side walls.

In one example, the air guide cover includes a cover body and a recessed area formed by the cover body, the recessed area and one of the two first side walls define the space, and the recessed area is communicated with the opening, the cover body is provided with a plurality of first holes located on edges thereof, one of the two first side walls provided with the input port includes a plurality of second holes corresponding to the plurality of first holes.

In one example, the cover body includes a mounting lip located on the side of the air guide cover with the opening, and a plurality of third holes located on the mounting lip.

In one example, the cover body is formed with a recessed portion, and the at least one recessed portion is formed with at least one of the plurality first holes.

In addition to the above, the invention further provides an air guide cover applied to a power supply, including a cover body, a recessed area, and an opening. The cover body includes a plurality of first holes located on edges thereof, and the plurality of first holes correspond to a plurality of second holes located on one side of a power supply. The recessed area is formed by the cover body. The opening is located on a side of the cover body and communicated with the recessed area.

In one example, the cover body includes a mounting lip located on the side of the air guide cover with the opening, and a plurality of third holes located on the mounting lip.

In one example, the cover body is formed with a recessed portion, and the at least one recessed portion is formed with at least one of the plurality first holes.

Through the aforementioned examples, the invention provides the following advantages compared to conventional technologies:

The power supply of the invention allows the housing to be selectively assembled with the air guide cover without changing the original structure thereof, so that the heat dissipation airflow can be maintained smoothly after users adjusting the installation orientation of the conventional power supply. On the other hand, the power supply of the invention has two different installation forms. The users can decide the form of installing the power supply in the computer case according to wiring requirements.

### BRIEF DESCRIPTION OF THE DRAWINGS

FIG. 1 is a schematic structural diagram of the power supply of the invention.

FIG. 2 is an implementation schematic diagram (1) of the power supply of the invention.

FIG. 3 is an implementation schematic diagram (2) of the power supply of the invention.

FIG. 4 is a structural exploded view (1) of the power supply of the invention.

FIG. 5 is a structural exploded view (2) of the power supply of the invention.

FIG. 6 is a top sectional view of the power supply of the invention.

FIG. 7 is a front view of the power supply of the invention.

FIG. 8 is a top sectional view of an example of the invention.

### DETAILED DESCRIPTION OF THE PREFERRED EMBODIMENTS

The detailed description and technical content of the invention are as follows, with reference to the accompanying figures:

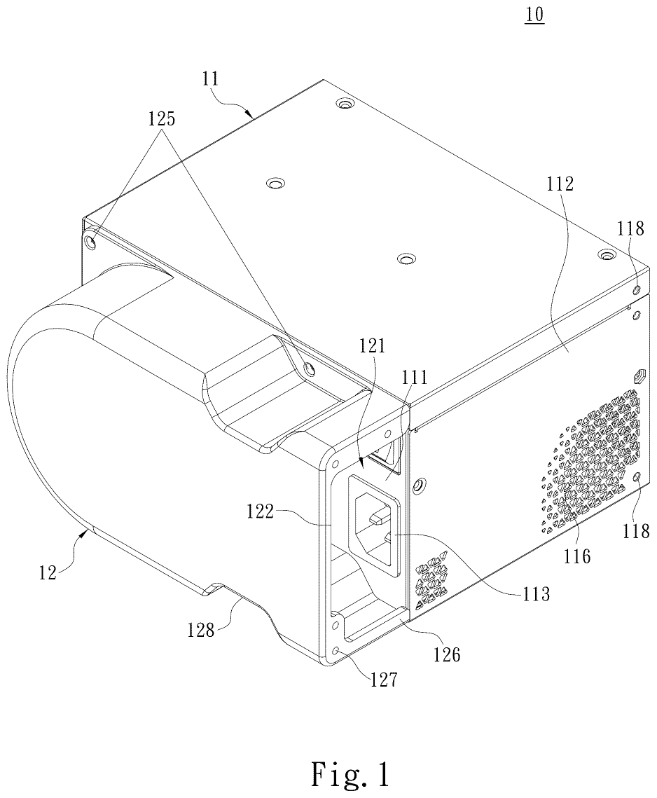

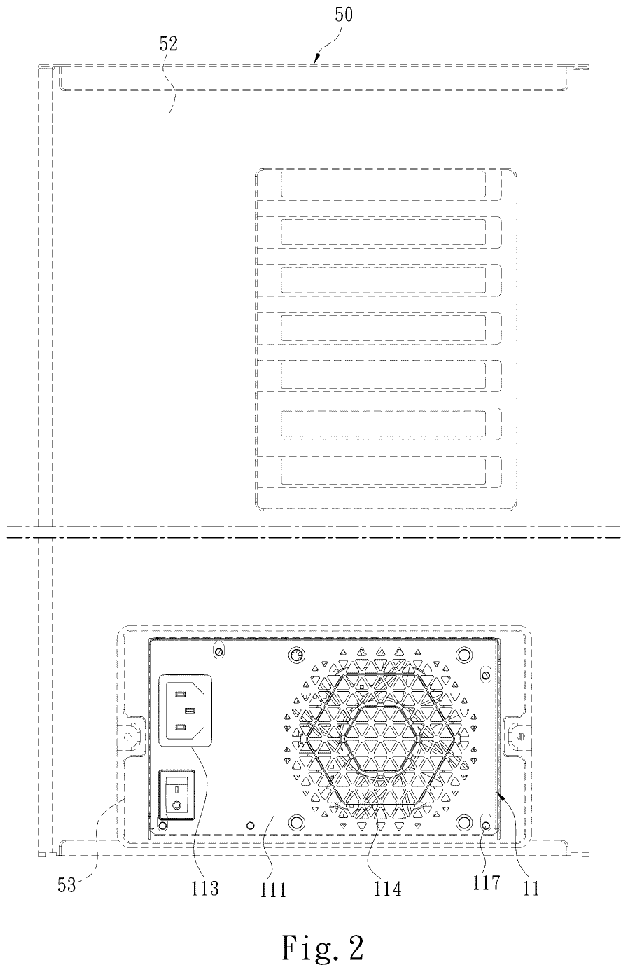

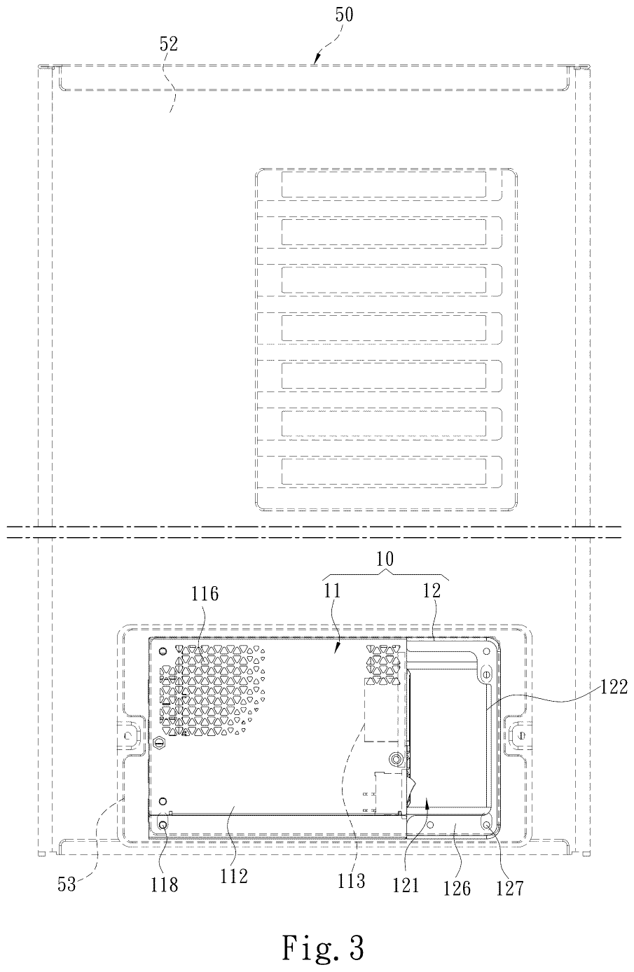

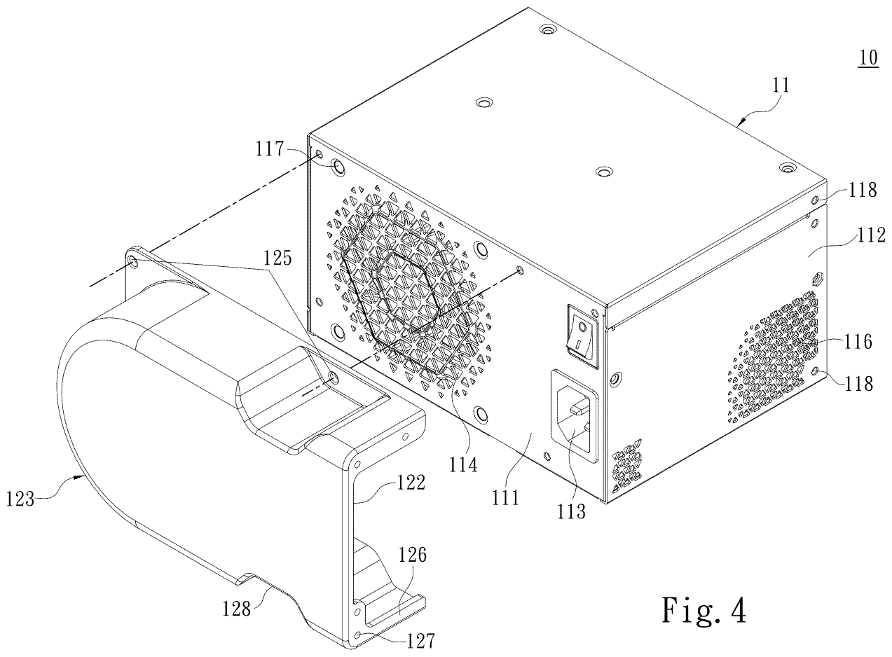

Please refer to FIG. 1, FIG. 2, FIG. 3, and FIG. 4. The invention provides a power supply 10, including a housing 11 and an air guide cover 12. The housing 11 includes two first side walls 111 in parallel, and two second side walls 112 in parallel and respectively connected to the two first side walls 111. One of the two first side walls 111 is provided with an input port 113 and at least one first air vent 114. The housing 11 includes existing components in conventional power supplies, such as a circuit board and a power conversion module, which will not be described in detail here.

The air guide cover 12 may be selectively covered on one of the two first side walls 111 with the input port 113, allowing the power supply 10 to have two forms, one form is shown in FIG. 2 that the housing 11 is separated from the air guide cover 12, and the other form is shown in FIG. 3 that the housing 11 is assembled with the air guide cover 12. The air guide cover 12 and one of the two first side walls 111 covered by the air guide cover 12 jointly define a space 121, communicated to the at least one first air vent 114. The air guide cover 12 includes an opening 122 that can be directly observable from one of the second side walls 112, the opening 122 is located on one side of the air guide cover 12 and communicated to the space 121. Further explanation can be provided by referring to FIG. 2. When the housing 11 is not assembled with the air guide cover 12, one of the two first side walls 111 with the input port 113 is not covered by the air guide cover 12, allowing a heat dissipation airflow inside the housing 11 to pass through the at least one first air vent 114 and circulate with air outside. Additionally, referring to FIG. 3, after the air guide cover 12 is assembled with the housing 11, one of the two first side walls 111 with the input port 113 is covered by the air guide cover 12, and the input port 113 faces the air guide cover 12. The heat dissipation airflow inside the housing 11 passes through the at least one first air vent 114, the space 121, and the opening 122, to circulate with the air outside.

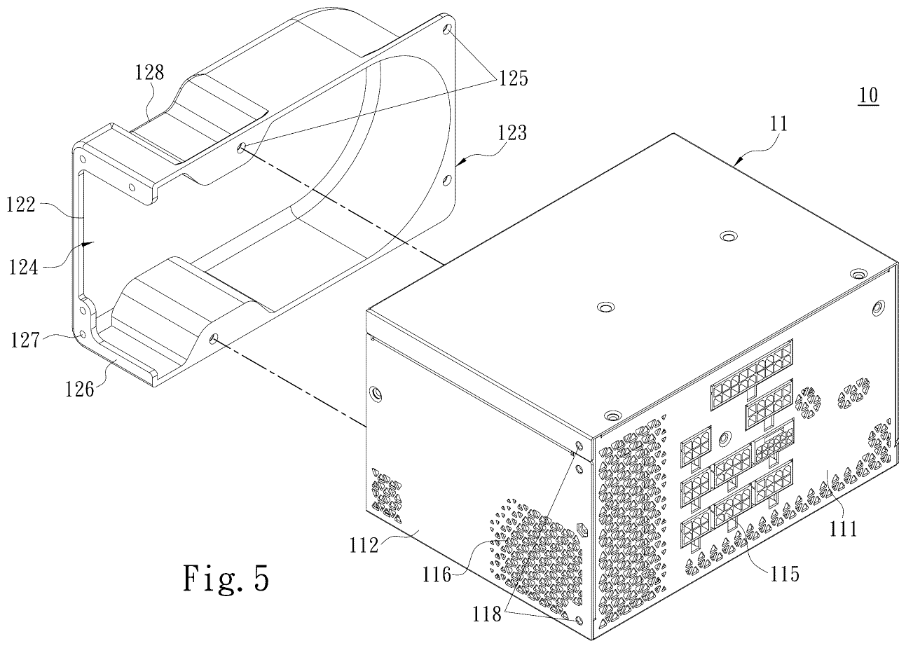

Please refer to FIG. 2, FIG. 3, FIG. 4, and FIG. 5, an implementation of the power supply 10 will now be described. For example, the power supply 10 is installed within a computer case 50, provided with multiple electronic components obtaining power from the power supply 10. In addition, the input port 113 is connected to an electric wire 51, through which the input port 113 receives power. Furthermore, to facilitate subsequent explanation, the computer case 50 includes a rear side 52 and a case outlet 53 located at the rear side 52. Referring to FIG. 2, when the air guide cover 12 is not installed onto the housing 11, one of the two first side walls 111 provided with the at least one first air vent 114 is oriented towards the case outlet 53. The heat dissipation airflow inside the housing 11 directly passes through the at least one first air vent 114 to exchange heat with the air outside. On the other hand, referring to FIG. 3, after the air guide cover 12 is installed onto the housing 11, an installation orientation of the housing 11 may be adjusted relative to the computer case 50. One of the two first side walls 111 with the at least one first air vent 114 faces a side of the computer case 50 without the case outlet 53; however, the opening 122 of the air guide cover 12 is communicated to the case outlet 53, allowing heat from the housing 11 to flow through the opening 122 of the air guide cover 12 to the case outlet 53 to exchange heat with the air outside. This design resolves the issue where, after adjusting an installation orientation of the power supply 10 within the computer case 50, the at least one first air vent 114 no longer faces the case outlet 53, and the heat dissipation airflow being obstructed by the computer case 50. It ensures that the heat dissipation airflow of the power supply 10 circulates smoothly with the air outside.

As can be seen from the above, the power supply 10 of the invention, compared to conventional power supplies, allows the users to adjust the installation orientation of the power supply 10 through an installation of the air guide cover 12, while maintaining smooth and continuous heat dissipation airflow with the air outside, unaffected by obstruction from the computer case 50. Furthermore, the invention is designed based on an original structure of the housing 11, so that when the users wish to adjust the installation orientation of a conventional power supply by installing the air guide cover 12, there is no need to replace the conventional power supply to avoid waste. On the other hand, the users can optionally assemble the air guide cover 12 to decide the installation orientation of the power supply 10.

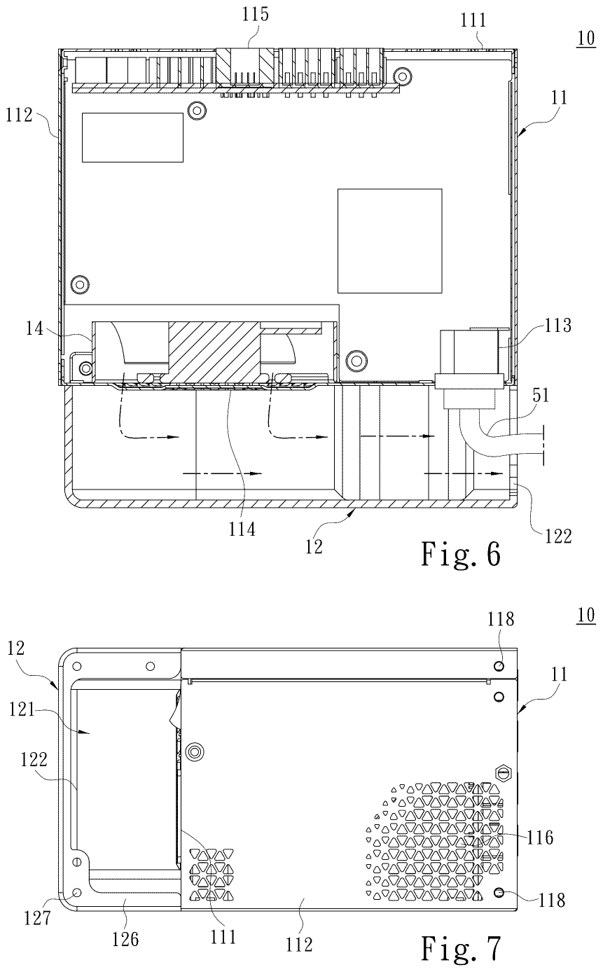

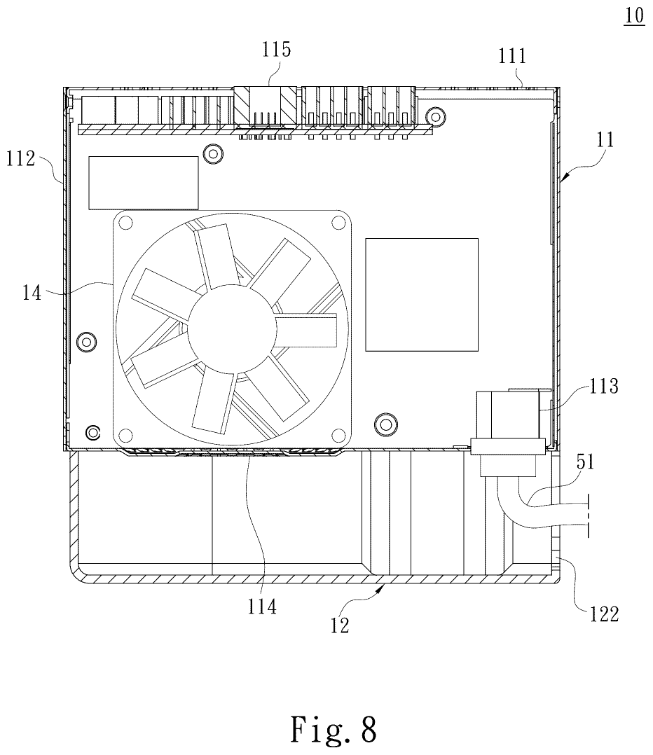

On the other hand, please refer to FIG. 2, FIG. 3, FIG. 6, and FIG. 8. In one example, the power supply 10 includes a fan 14 installed inside the housing 11. The fan 14 generates auxiliary airflow inside the housing 11 to assist with the heat dissipation of the power supply 10 since the space 121 communicates with the at least one first air vent 114 and the opening 122. A position of the fan 14 is not limited arrangements shown in FIG. 6 and FIG. 8. FIG. 6 merely illustrates that the fan 14 can be positioned on a side wall of the housing 11, while FIG. 8 illustrates the fan 14 can be positioned at a top of the housing 11. In another example, at least one of the two second side walls 112 is provided with at least one second air vent 116. The at least one second air vent 116 may be communicated with the interior of the computer case 50 when at least one of the second side walls 112 is oriented towards the interior of the computer case 50, thereby facilitating the power supply 10 in maintaining its heat dissipation capability after the installation orientation of the power supply 10 is adjusted.

Please refer to FIG. 2, FIG. 3, FIG. 4, FIG. 5, and FIG. 6. In one example, at least one of the two first side walls 111 or at least one of the two second side walls 112 is provided with at least one output port 115. Taking an example that the at least one output port 115 is located opposite to the input port 113, when the air guide cover 12 does not assemble with the housing 11, the at least one output port 115 is oriented towards the interior of the computer case 50, allowing the electronic components inside the computer case 50 to be directly connected to the at least one output port 115. After the air guide cover 12 is assembled with the housing 11, the opening 122 faces the rear side 52, and the at least one output port 115 is positioned on one of two sides adjacent to the rear side 52, making the power supply 10 is in a side plug-in configuration.

Please refer to FIG. 2, FIG. 3, FIG. 4, FIG. 5, and FIG. 6. In one example, the air guide cover 12 includes a cover body 123 and a recessed area 124 formed by the cover body 123. The recessed area 124 of the air guide cover 12 is provided for defining the space 121 with one of the two first side walls 111, and the recessed area 124 is communicated with the opening 122. Furthermore, the cover body 123 is provided with a plurality of first holes 125 located on edges thereof, and one of the two first side walls 111 with the input port 113 is provided with a plurality of second holes 117 corresponding to the plurality of first holes 125. Positions of the plurality of second holes 117 are arranged on the housing 11 based on the specifications of conventional power supplies, allowing the housing 11 to be directly assembled with the air guide cover 12 without the need for additional holes on the housing 11.

In one example, a length of each of the two first side walls 111 is greater than that of each of the two second side walls 112. The length of each of the two first side walls 111 is equal to a total length of each of the two second side walls 112 plus the air guide cover 12 after the air guide cover 12 is assembled with the housing 11. In another example, the cover body 123 includes a mounting lip 126 positioned on the side of the air guide cover 12 with the opening 122, and a plurality of third holes 127 located on the mounting lip 126. At least one of the two second side walls 112 is provided with a plurality of fourth holes 118.

Please refer to FIG. 4 and FIG. 5. In one example, the cover body 123 is formed with at least one recessed portion 128, wherein the at least one recessed portion 128 is formed with at least one of the plurality first holes 12 to be disposed corresponding to at least one of the plurality of second holes 117 in position, facilitating an installation of the air guide cover 12 with the housing 11.

What is claimed is:

1. A power supply, comprising:
a housing, comprising two first side walls in parallel, and two second side walls in parallel and respectively connected to the two first side walls, one of the two first side walls comprising an input port and at least one first air vent; and
an air guide cover, selectively covering one of the two first side walls provided with the input port, and a space defined by the air guide cover and one of the two first side walls with the input port, the space communicating with the at least first air vent, the air guide cover comprising an opening which is observable from one of the two second side walls, and the opening located on one side of the air guide cover and communicated with the space.

2. The power supply as claimed in claim 1, wherein at least one of the two first side walls and the two second side walls is provided with at least one input port.

3. The power supply as claimed in claim 1, wherein at least one of the two second side walls is provided with at least one second air vent.

4. The power supply as claimed in claim 1, wherein a length of each of the two first side walls is larger than that of each of the two second side walls.

5. The power supply as claimed in claim 1, wherein the air guide cover comprises a cover body and a recessed area formed by the cover body, the recessed area and one of the two first side walls define the space, and the recessed area is communicated with the opening, the cover body is provided with a plurality of first holes located on edges thereof, one of the two first side walls provided with the input port comprises a plurality of second holes corresponding to the plurality of first holes.

6. The power supply as claimed in claim 5, wherein the cover body comprises a mounting lip located on the side of the air guide cover with the opening, and a plurality of third holes located on the mounting lip.

7. The power supply as claimed in claim 5, wherein the cover body is formed with at least one recessed portion, and the at least one recessed portion is formed with at least one of the plurality first holes.

8. An air guide cover applied to a power supply, comprising:
a cover body, comprising a plurality of first holes located on edges thereof, and the plurality of first holes corresponding to a plurality of second holes located on one side of a power supply;
a recessed area, formed by the cover body;
an opening, located on a side of the cover body and communicated with the recessed area.

9. The air guide cover applied to the power supply as claimed in claim 8, wherein the cover body comprises a mounting lip located on the side of the air guide cover with the opening, and a plurality of third holes located on the mounting lip.

10. The air guide cover applied to the power supply as claimed in claim 9, wherein the cover body is formed with at least one recessed portion, and the at least one recessed portion is formed with at least one of the plurality first holes.
